(19) United States
(12) Patent Application Publication
(10) Pub. No.: US 2025/0289039 A1
(43) Pub. Date: Sep. 18, 2025

(54) DEVICE FOR MANUFACTURING DISPLAY APPARATUS AND METHOD OF MANUFACTURING DISPLAY APPARATUS

(71) Applicant: Samsung Display Co., LTD., Yongin-si (KR)

(72) Inventors: Sungmin HUCH, Yongin-si (KR); Seungwon LEE, Yongin-si (KR)

(21) Appl. No.: 18/979,968

(22) Filed: Dec. 13, 2024

(30) Foreign Application Priority Data
Mar. 14, 2024 (KR) 10-2024-0035984

(51) Int. Cl. B08B 7/00; C23C 16/04; C23C 16/44; C23C 16/46; H10K 59/12; H10K 71/00

(52) U.S. Cl. CPC B08B 7/00; C23C 16/042; C23C 16/4405; C23C 16/46; H10K 59/1201; H10K 71/811

(57) ABSTRACT

A device for manufacturing a display apparatus includes a first chamber, a second chamber connected to the first chamber, a first controller which controls the second chamber, a pressure adjuster connected to the first chamber, and a second controller which controls the pressure adjuster. The first controller, while a cleaning process of the first chamber is performed, controls at least one of a flow rate of a first material flowing into the second chamber and a flow rate of a second material flowing into the second chamber, and the second controller, while the cleaning process of the first chamber is performed, controls an opening rate of the pressure adjuster and maintains a pressure in the first chamber at a preset range.

This application claims priority to Korean Patent Application No. 10-2024-0035984, filed on Mar. 14, 2024, and all the benefits accruing therefrom under 35 U.S.C. § 119, the content of which in its entirety is herein incorporated by reference.

### BACKGROUND

### 1. Field

Embodiments relate to a device for manufacturing a display apparatus and a method of manufacturing a display apparatus. A display apparatus may be a display apparatus including a light-emitting diode.

### 2. Description of the Related Art

Display apparatuses visually display data. Display apparatuses may display images using light-emitting diodes. To display images, a display apparatus may include a plurality of pixels in a pattern form. In this case, various layers including an emission layer may be included in the plurality of pixels having a pattern form. These layers may be arranged in different patterns according to the kind thereof.

Each layer of a display apparatus may be formed by depositing a deposition material by a mask defining an opening corresponding to a pattern to be formed on a substrate. The deposition of the deposition material may be performed within a chamber of a device for manufacturing a display apparatus. After the deposition material is deposited on the substrate, a cleaning material may be injected into the chamber to remove the deposition material remaining on elements inside the chamber. The cleaning material may react with the deposition material remaining in a solid state to vaporize the deposition material, and the vaporized deposition material may be discharged to the outside of the chamber through a valve provided in the chamber.

### SUMMARY

Before the gases in the chamber are discharged to the outside of the chamber through the valve, the cleaning material have to remain in the chamber for a sufficient period of time (or time duration) to ensure sufficient cleaning. When a residence time duration of the cleaning material in the chamber is secured, a total time duration desired for cleaning may be shortened. Accordingly, conditions to ensure the residence time duration of the cleaning material in the chamber are desired to be met.

Additional features will be set forth in part in the description which follows and, in part, will be apparent from the description, or may be learned by practice of the presented embodiments of the disclosure.

In an embodiment of the disclosure, a device for manufacturing a display apparatus includes a first chamber, a second chamber connected to the first chamber, a first controller which controls the second chamber, a pressure adjuster connected to the first chamber, and a second controller which controls the pressure adjuster. The first controller, while a cleaning process of the first chamber is performed, controls at least one of a flow rate of a first material flowing into the second chamber and a flow rate of a second material flowing into the second chamber, and the second controller, while a cleaning process of the first chamber is performed, controls an opening rate of the pressure adjuster and maintains a pressure in the first chamber at a preset range.

In an embodiment, the first material may include a first element, and the device for manufacturing the display apparatus may generate first radicals of the first element by applying energy to the first material in the second chamber.

In an embodiment, the first element may be argon.

In an embodiment, the second material may include a second element, and the device for manufacturing the display apparatus may generate second radicals of the second element by the first radicals of the first element in the second chamber.

In an embodiment, the second element may be fluorine.

In an embodiment, the first radicals of the first element and the second radicals of the second element, generated in the second chamber, may be injected into the first chamber.

In an embodiment, the opening rate of the pressure adjuster may be about 30% to about 35%.

In an embodiment, the flow rate of the second material flowing into the second chamber may be 50% or more of the flow rate of the first material flowing into the second chamber.

In an embodiment, the preset range of the pressure in the first chamber may be about 1.5 Torr to about 2.5 Torr.

In an embodiment of the disclosure, a method of manufacturing a display apparatus includes depositing a deposition material on a substrate in a first chamber, and cleaning the deposition material remaining in the first chamber. In the cleaning the deposition material, at least one of a flow rate of a first material flowing into a second chamber connected to the first chamber, and a flow rate of a second material flowing into the second chamber is adjusted, and an opening rate of a pressure adjuster connected to the first chamber is adjusted thereby maintaining pressure in the first chamber at a preset range.

In an embodiment, the first material may include a first element, and the method may further include generating first radicals of the first element by applying energy to the first material in the second chamber.

In an embodiment, the first element may be argon.

In an embodiment, the second material may include a second element, and the method may further include generating second radicals of the second element by the first radicals of the first element in the second chamber.

In an embodiment, the second element may be fluorine.

In an embodiment, in the generating the second radicals of the second element, the first material and the second material may be injected together at a preset ratio into the second chamber.

In an embodiment, the method may further include injecting, into the first chamber, the first radicals of the first element and the second radicals of the second element generated in the second chamber.

In an embodiment, the opening rate of the pressure adjuster may be about 30% to about 35%.

In an embodiment, the flow rate of the first material flowing into the second chamber may be 50% or more of the flow rate of the second material flowing into the second chamber.

In an embodiment, the preset range of the pressure in the first chamber may be about 1.5 Torr to about 2.5 Torr.

In an embodiment, in the maintaining the pressure in the first chamber at the preset range, the opening rate of the pressure adjuster may be increased when a sum of the flow rate of the first material and the flow rate of the second material increases, and the opening rate of the pressure adjuster may be reduced when a sum of the flow rate of the first material and the flow rate of the second material is reduced.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a cross-sectional view of an embodiment of a device for manufacturing a display apparatus;

FIGS. 2, 3, 4, 5, 6, and 7 are cross-sectional views showing an embodiment of stages in a process of a method of manufacturing a display apparatus;

FIG. 8 is a bar graph showing a cleaning time duration according to an opening rate of a valve;

FIG. 9 is a bar graph showing a cleaning time duration according to an injection flow rate of a first material;

FIG. 10 is a plan view of an embodiment of a display apparatus manufactured using a device for manufacturing a display apparatus or a method of manufacturing a display apparatus; and

FIG. 11 is a cross-sectional view of an embodiment of a display apparatus manufactured using a device for manufacturing a display apparatus or a method of manufacturing a display apparatus.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, illustrative embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms. Hereinafter, when described with reference to the drawings, identical or corresponding elements will be assigned the same reference numerals and repeated description thereof will be omitted. While such terms as “first” and “second” may be used to describe various elements, such elements must not be limited to the above terms. The above terms are used to distinguish one element from another. The singular forms “a,” “an,” and “the” as used herein are intended to include the plural forms as well unless the context clearly indicates otherwise. It will be understood that the terms “comprise,” “comprising,” “include” and/or “including” as used herein specify the presence of stated features or elements but do not preclude the addition of one or more other features or elements. It will be further understood that, when a layer, region, or element is referred to as being “on” another layer, region, or element, it may be directly or indirectly on the other layer, region, or element. That is, for example, intervening layers, regions, or elements may be present. Sizes of elements in the drawings may be exaggerated or reduced for convenience of explanation. As an example, the size and thickness of each element shown in the drawings are arbitrarily represented for convenience of description, and thus, the disclosure is not necessarily limited thereto. In the case where an illustrative embodiment may be implemented differently, a specific process order may be performed in the order different from the described order. As an example, two processes successively described may be simultaneously performed substantially and performed in the opposite order. In the specification, “A and/or B” means A or B, or A and B. In the specification, “at least one of A and B” means A or B, or A and B. The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

The term such as “controller” as used herein is intended to mean a hardware component that performs a predetermined function. The hardware component may include a circuitry such as a field-programmable gate array (“FPGA”) or an application-specific integrated circuit (“ASIC”), for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

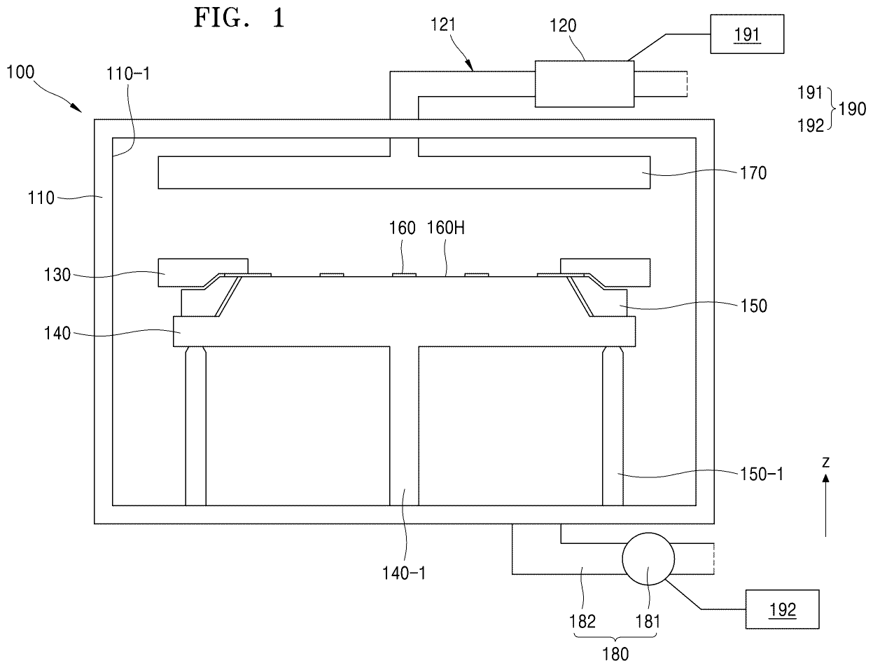

FIG. 1 is a cross-sectional view of an embodiment of an apparatus 100 for manufacturing a display apparatus.

Referring to FIG. 1, the apparatus 100 for manufacturing a display apparatus may include a first chamber 110, a second chamber 120, a shadow frame 130, a susceptor 140, a mask supporter 150, a deposition mask 160, a diffuser 170, a pressure adjuster 180, and a controller 190.

A space (also referred to as an internal space) 110-1 may be defined in the first chamber 110, and although not shown in FIG. 1, a portion of the first chamber 110 may be open. A gate valve may be installed in the open portion of the first chamber 110. In this case, the open portion of the first chamber 110 may be opened or closed according to an operation of the gate valve.

The second chamber 120 may be disposed outside the first chamber 110. In an embodiment, the second chamber 120 may be a remote plasma source chamber (“RPSC”). In an embodiment, the second chamber 120 may be a chamber which supplies plasma to the first chamber 110. In an embodiment, the second chamber 120 may be less than the first chamber 110 in size. In an embodiment, the second chamber 120 may be connected to an injection pipe 121. In an embodiment, the injection pipe 121 may include a plurality of pipes and be connected to a plurality of sides of the second chamber 120. In an embodiment, some of the pipes of the injection pipe 121 may be connected to one side of the second chamber 120, and others may be connected to another side of the second chamber 120. In an embodiment, a portion of the injection pipe 121 may connect the first chamber 110 to the second chamber 120. In an embodiment, a portion of the injection pipe 121 may connect the internal space 110-1 of the first chamber 110 to the internal space of the second chamber 120 by fluid communication.

The shadow frame 130 may be disposed inside the first chamber 110. The shadow frame 130, together with the mask supporter 150, may hold the deposition mask 160 therebetween to fix the deposition mask 160. The shadow frame 130 may define an opening overlapping the susceptor 140 in the center. The shadow frame 130 may be raised or lowered in a z direction through a separate linear operator (not shown), and accordingly, an interval between the shadow frame 130 and the mask supporter 150 may be adjusted. FIG. 1 shows the case where the shadow frame 130 is lowered to contact the deposition mask 160.

The susceptor 140 may be disposed below the shadow frame 130 and the deposition mask 160. The susceptor 140 may support and heat a substrate during a deposition process. The susceptor 140 may include a separate heat source (not shown) that may heat the substrate disposed on its upper surface. The susceptor 140 may be connected to the first chamber 110 through a susceptor supporter 140-1. The susceptor 140 may be raised or lowered in the z direction through a linear operator (not shown) separately provided in the susceptor supporter 140-1, for example.

The mask supporter 150 may be disposed between the shadow frame 130 and the susceptor 140. Similar to the shadow frame 130, the mask supporter 150 may be open in its center. An opening of the shadow frame 130 and an opening of the mask supporter 150 may overlap the susceptor 140. The mask supporter 150 may be connected to an elevator 150-1 disposed therebelow. The mask supporter 150 may be raised or lowered in the z direction through a linear operator separately provided in the elevator 150-1, and accordingly, an interval between the shadow frame 130 and the mask supporter 150 may be adjusted. Through this, the deposition mask 160 may be held between the shadow frame 130 and the mask supporter 150.

The deposition mask 160 may be disposed between the shadow frame 130 and the mask supporter 150 and held by the two elements. In addition, the deposition mask 160 is not always held by the shadow frame (also referred to as a shadow mask) 130 and the mask supporter 150. In an embodiment, the interval between the shadow frame 130 and the mask supporter 150 may be adjusted to release the deposition mask 160. The deposition mask 160 may be loaded into the first chamber 110 from the outside and be replaced. A plurality of openings 160H may be defined in the deposition mask 160, and the openings 160H may define regions in which a deposition material is deposited. The disclosure is not necessarily limited to the configuration or size of the openings 160H of the deposition mask 160 shown in FIG. 1.

The diffuser 170 may be disposed to face the deposition mask 160 and the susceptor 140. In an embodiment, the diffuser 170 may receive the deposition material therein or receive the deposition material from the outside. In an embodiment, the diffuser 170 may vaporize or sublimate the deposition material by applying heat to the deposition material. In an embodiment, the diffuser 170 may also receive a gaseous deposition material from the outside. In an embodiment, the diffuser 170 may also receive a material from the second chamber 120. In this case, the diffuser 170 may be connected to the second chamber 120 through the injection pipe 121. In an embodiment, the diffuser 170 may include a nozzle which diffuses a gaseous deposition material to the first chamber 110. The diffuser 170 may be fixed inside the first chamber 110, or disposed inside the first chamber 110 to be linearly movable in one direction. Hereinafter, for convenience of description, the case where the diffuser 170 is disposed to be fixed inside the first chamber 110 is mainly described in detail.

The pressure adjuster 180 may be connected to the first chamber 110 and may adjust the inner pressure of the first chamber 110. In an embodiment, the pressure adjuster 180 may adjust the inner pressure of the first chamber 110 to be equal or similar to the atmospheric pressure. In addition, the pressure adjuster 180 may adjust the inner pressure of the first chamber 110 to be equal or similar to a vacuum state. The pressure adjuster 180 may include a connection pipe 182 connected to the first chamber 110, a valve 181 installed in the connection pipe 182, and a pump (not shown). In this case, external air may be introduced through the connection pipe 182 or gas inside the first chamber 110 may leak out to the outside through the connection pipe 182 according to an operation of the pump. Hereinafter, the case where the gas inside the first chamber 110 leaks out to the outside is mainly described. In this case, a flow rate through the connection pipe 182 may be adjusted according to the opening rate of the valve 181.

The controller 190 may control elements of the apparatus 100 for manufacturing the display apparatus. The controller 190 may include one system which controls a plurality of elements of the apparatus 100 for manufacturing the display apparatus, or include a plurality of systems which individually control each of the plurality of elements of the apparatus 100 for manufacturing the display apparatus. In an alternative embodiment, the controller 190 may include portions respectively connected to the plurality of elements of the apparatus 100 for manufacturing the display apparatus, and one centrally controlled system. Hereinafter, the case where the controller 190 includes a first controller 191 and a second controller 192, and the first controller 191 and the second controller 192 individually control the elements of the apparatus 100 for manufacturing the display apparatus is mainly described in detail. However, the disclosure is not necessarily limited thereto.

The first controller 191 may be connected to the second chamber 120 and may control the second chamber 120 and the injection pipe 121. In an embodiment, the first controller 191 may control a flow rate of a material flowing into the second chamber 120. In an embodiment, the first controller 191 may be controlled to control the flow rate of the material flowing through the injection pipe 121.

The second controller 192 may be connected to the pressure adjuster 180 and may control the valve 181 and/or the connection pipe 182 of the pressure adjuster 180. In an embodiment, the second controller 192 may control the flow rate of a material leaking out to the outside through the connection pipe 182 by controlling the opening rate of the valve 181. The pressure in the first chamber 110 may be controlled by the control of the first controller 191 and the second controller 192. Predetermined operations of the second chamber 120, the injection pipe 121, the connection pipe 182, and the valve 181 according to the control of the first controller 191 and the second controller 192 are described below.

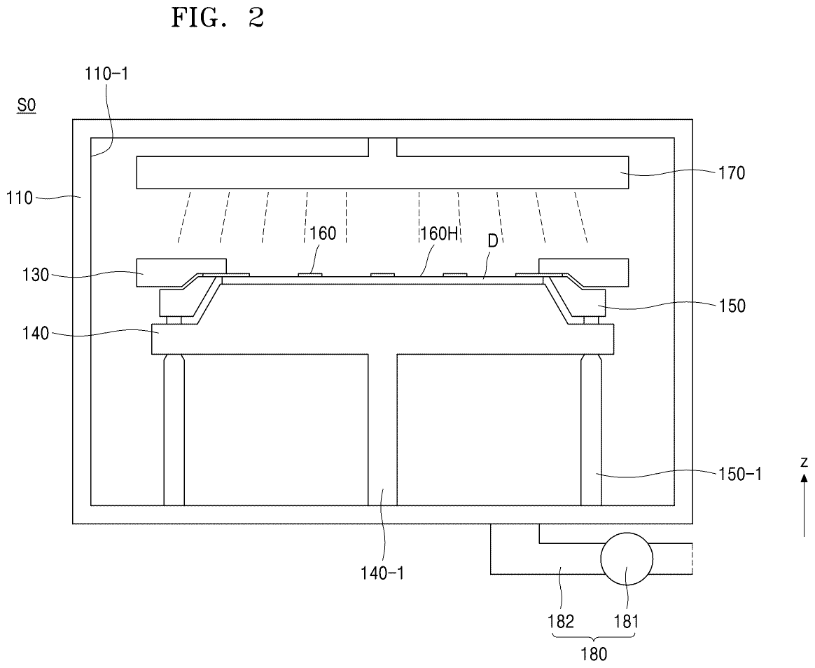

FIGS. 2 to 7 are cross-sectional views showing an embodiment of stages in a process of a method of manufacturing a display apparatus.

Referring to FIG. 2, a stage 0 (S0) including a deposition stage is shown.

First, when the pressure adjuster 180 makes the inside of the first chamber 110 equal or similar to the atmospheric pressure, a display substrate D may be loaded into the first chamber 110 from the outside. In this case, the display substrate D may be loaded into the first chamber 110 in various methods. In an embodiment, the display substrate D may be loaded into the inside of the first chamber 110 from the outside of the first chamber 110 by a robot arm disposed outside the first chamber 110.

As shown, the deposition mask 160 may be disposed in the first chamber 110. In an embodiment, the deposition mask 160 may be held between the shadow frame 130 and the mask supporter 150. In an embodiment, similar to the display substrate D, the deposition mask 160 may be loaded into the first chamber 110 from the outside of the first chamber 110. Hereinafter, for convenience of description, the case where only the display substrate D is loaded into the inside of the first chamber 110 from the outside of the first chamber 110 with the deposition mask 1600 disposed inside the first chamber 110 is mainly described in detail.

When the display substrate D is loaded into the inside of the first chamber 110, the display substrate D may be seated on the susceptor 140. In this case, the positions of the display substrate D and the deposition mask 160 may be captured by a vision portion (not shown) separately provided, and the position of the display substrate D and/or the position of the deposition mask 160 may be fine-adjusted. Through this, the display substrate D and the deposition mask 160 may be aligned.

While the display substrate D is loaded into the first chamber 110, the deposition mask 160 may be held between the shadow frame 130 and the mask supporter 150. In an embodiment, the deposition mask 160 may be sufficiently apart from the susceptor 140 such that the display substrate D is disposed between the deposition mask 160 and the susceptor 140. To implement this, the shadow frame 130 and the mask supporter 150 may be also sufficiently apart from the susceptor 140. The display substrate D is loaded into the first chamber 110, disposed between the deposition mask 160 and the susceptor 140, aligned with the deposition mask 160, and then the shadow frame 130, the mask supporter 150, and the deposition mask 160 may be integrally lowered (alternatively, may move in a-z direction). Accordingly, the deposition mask 160 may be closely attached to the display substrate D. In this case, the display substrate D may contact the upper surface of the susceptor 140.

Next, the pressure adjuster 180 may maintain the pressure in the first chamber 110 at a state equal or similar to vacuum by discharging the gas in the first chamber 110 to the outside.

Next, a deposition stage may be performed. In an embodiment, the deposition stage may be performed using chemical vapor deposition (“CVD”). In this case, the diffuser 170 operates to diffuse the deposition material into the first chamber 110 in a gas or vapor state.

Next, alternatively, substantially simultaneously, a heat source (not shown) of the susceptor 140 may heat the susceptor 140 and heat the display substrate D in contact with the susceptor 140. In this case, a portion of the surface of the display substrate D overlapping the opening 160H of the deposition mask 160 may contact the deposition material diffused in the first chamber 110 by the diffuser 170. The deposition material may cause a chemical reaction with or on the surface of the heated display substrate D, and a layer may be formed on the display substrate D in a region overlapping the opening 160H of the deposition mask 160. In this case, the deposition mask 160 may provide a deposition region equal or similar to a deposition region determined in advance. In an embodiment, the above-described operation may be repeatedly performed on a plurality of display substrates D.

After the deposition process is performed, the deposition material entirely diffused in the first chamber 110 may be seated on the surfaces of the elements in the first chamber 110. In an embodiment, a portion of the deposition material may be seated on the surfaces of the deposition mask 160, the shadow frame 130, the mask supporter 150, and/or the susceptor 140. The seated deposition material does not flow out of the first chamber 110 when the gas in the first chamber 110 is removed through the pressure adjuster 180, but may remain on the surfaces of the elements in the first chamber 110 in a solid state, for example. Accordingly, a cleaning operation of removing the seated deposition material from the first chamber 110 is desired. The cleaning operation may include a process of separating the seated deposition material from the surfaces of the elements in the first chamber 110 and discharging the deposition material to the outside of the first chamber 110. In an embodiment, the cleaning operation may include a process of converting the solid state deposition material into a gas, causing the deposition material to flow, and flowing the deposition material out of the first chamber 110.

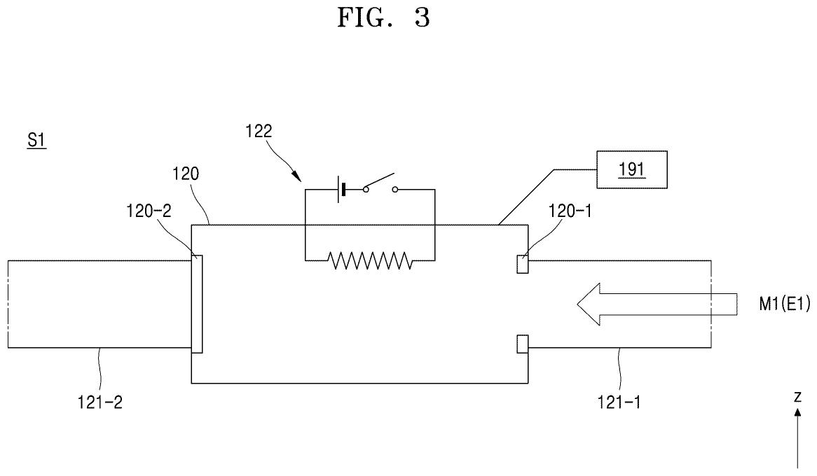

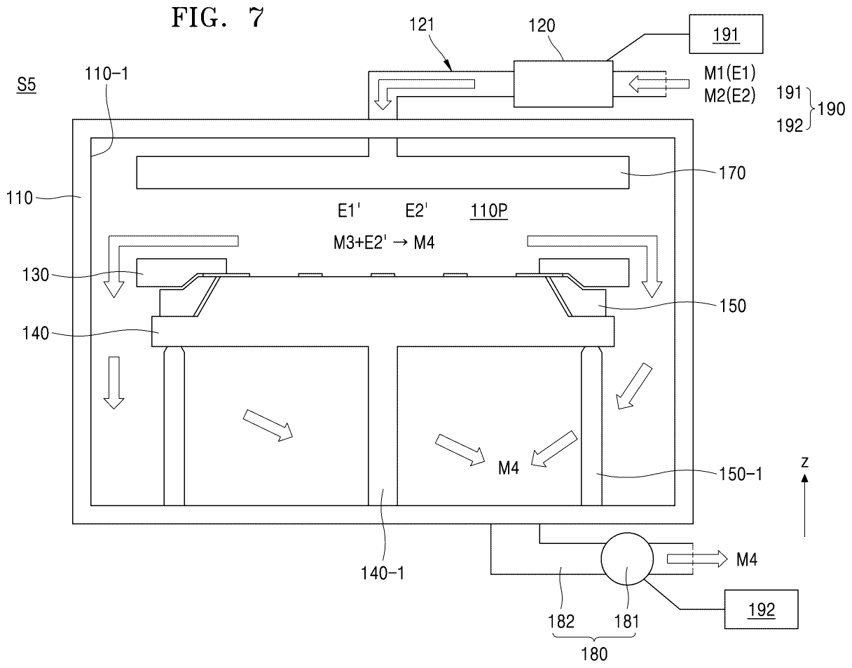

Hereinafter, the cleaning operation is described in detail with reference to a first stage S1 (refer to FIG. 3) to a fifth stage S5 (refer to FIG. 7) of FIGS. 3 to 7.

Referring to FIG. 3, a first injection pipe 121-1 may be connected to one side of the second chamber 120. A material may be injected into the second chamber 120 through the first injection pipe 121-1. In other words, the first injection pipe 121-1 may be an injection pipe facing the second chamber 120. A first gate 120-1 may be installed in a portion where the first injection pipe 121-1 is connected to the second chamber 120. A flow rate of the material flowing into the second chamber 120 through the first injection pipe 121-1 may be controlled by the first gate 120-1. In an embodiment, the first gate 120-1 may be controlled by the first controller 191.

A second injection pipe 121-2 may be connected to another side of the second chamber 120. A preset material may move from the second chamber 120 to the first chamber 110 (refer to FIG. 2) through the second injection pipe 121-2. In other words, the second injection pipe 121-2 may be an injection pipe facing the first chamber 110 (refer to FIG. 2). A second gate 120-2 may be installed in a portion where the second injection pipe 121-2 is connected to the second chamber 120. A flow rate of a material leaking out of the second chamber 120 (or flowing into the first chamber 110 (refer to FIG. 2)) through the second injection pipe 121-2 may be controlled by opening/closing the second gate 120-2. In an embodiment, the second gate 120-2 may be controlled by the first controller 191.

A power portion 122 may apply a current to the second chamber 120. In an embodiment, the power portion 122 may include an arbitrary device capable of applying a voltage, a switch of an arbitrary kind, and a resistor disposed in the second chamber 120. The disclosure is not necessarily limited thereto and the power portion 122 may have an arbitrary other construction capable of applying a current into the second chamber 120.

In the first stage S1, the first gate 120-1 is opened and the material may flow into the second chamber 120. In an embodiment, a first material M1 may flow through the first injection pipe 121-1, pass through the opened first gate 120-1, and flow into the first chamber 110. In an embodiment, the second gate 120-2 may be in a closed state. In an embodiment, the power portion 122 may be in a non-operating state. In an embodiment, the first material M1 may include a first element E1. In an embodiment, the first material M1 may include argon (Ar) gas. In an embodiment, the first element E1 may be argon (Ar). In an embodiment, the first controller 191 may control a flow rate of the first material M1 injected into the second chamber 120.

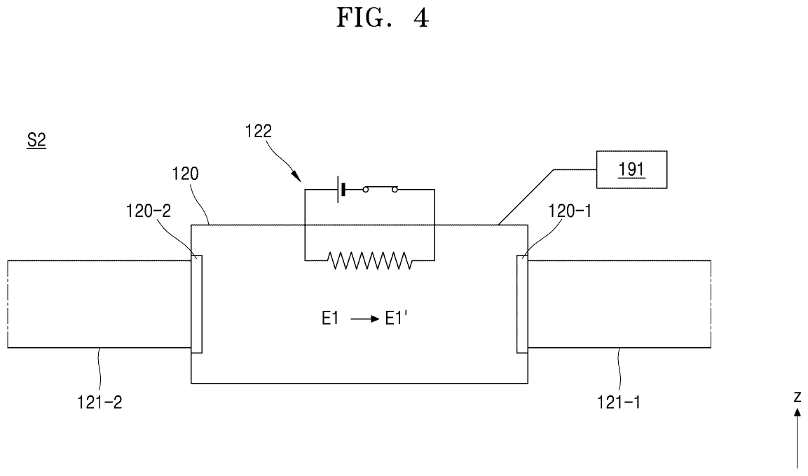

Referring to FIG. 4, the second stage S2 may be performed. A sufficient amount of first element E1 is disposed in the second chamber 120, and then the first gate 120-1 may be closed. In this case, the first controller 191 may block the flowing of the material in the first injection pipe 121-1. Next, the power portion 122 may operate to apply energy to the first element E1 in the second chamber 120. In an embodiment, as shown in FIG. 4, a current may be transferred into the second chamber 120 by closing a switch provided to the power portion 122, and substantially simultaneously, resistance heat may be transferred into the second chamber 120 by transferring the current to the resistor provided in the second chamber 120. The disclosure is not necessarily limited to this method and any suitable method that may apply energy to the first element E1 may be used.

In an embodiment, at least a portion of the first element E1 may become a plasma state by the energy applied into the second chamber 120. In an embodiment, at least a portion of the first element E1 may become radicals, e.g., first radicals E1′. In an embodiment, the first element E1 may be argon (Ar), and the first radicals E1′ may be argon (Ar) radicals.

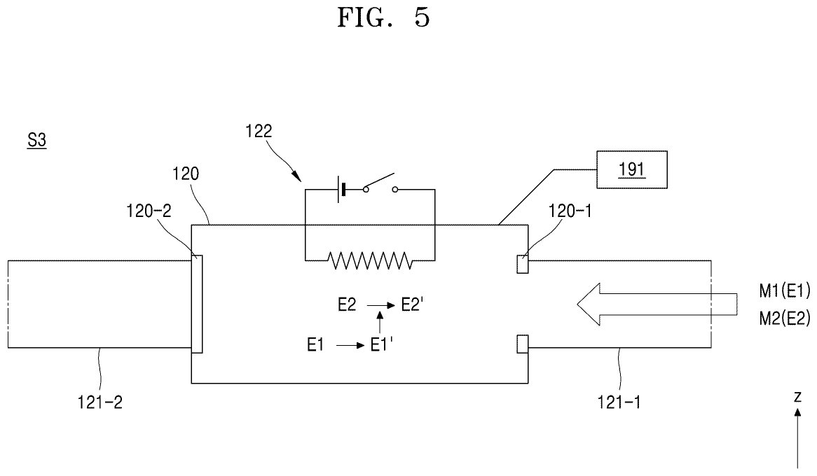

Referring to FIG. 5, a third stage S3 may be performed. In the third stage S3, the first gate 120-1 is opened and the material may flow into the second chamber 120. In an embodiment, the first material M1 and a second material M2 may flow through the first injection pipe 121-1, pass through the opened first gate 120-1, and flow into the second chamber 120. In an embodiment, the second gate 120-2 may be in a closed state. In an embodiment, there may be the first element E1 and the first radicals E1′ in the second chamber 120. The first material M1 and the second material M2 may respectively flow into the second chamber 120 through separate pipes, or may be merged into one pipe in the outside of the second chamber 120 and then simultaneously flow into the second chamber 120. Hereinafter, for convenience of description, the case where the first material M1 and the second material M2 are merged into one pipe (e.g., the first injection pipe 121-1) in the outside of the second chamber 120 and then simultaneously flow into the second chamber 120 is mainly described.

The first controller 191 may control the flow rate of the first material M1 and the flow rate of the second material M2. In an embodiment, the first material M1 and the second material M2 may respectively flow along separate pipes, and then the pipes may be merged in the first injection pipe 121-1. In this case, the flow rate of the first material M1 and the flow rate of the second material M2 in the separate pies may be controlled. Through this, after the merging, the ratio of the flow rate of the first material M1 to the flow rate of the second material M2 within the first injection pipe 121-1 may be set. In an embodiment, the first controller 191 may control each of the absolute value of the flow rate of the first material M1 and the absolute value of the flow rate of the second material M2. In an embodiment, the first controller 191 may control the ratio of the flow rate of the first material M1 to the flow rate of the second material M2. In an embodiment, the flow rate of the second material M2 flowing into the second chamber 120 may be 50% or more of the flow rate of the first material M1 flowing into the second chamber 120. In an embodiment, the flow rate of the second material M2 flowing into the second chamber 120 may be about 50% of the flow rate of the first material M1 flowing into the second chamber 120. In an embodiment, the flow rate of the first material M1 may be about 32 liters per minute (L/min), and the flow rate of the second material M2 may be about 16 L/min.

As described above, the first material M1 may include the first element E1. The second material M2 may include a second element E2. In an embodiment, the first material M1 and the second material M2 may be different from each other. In an embodiment, the first element E1 and the second element E2 may be different from each other. In an embodiment, the first material M1 may include argon (Ar) gas. In an embodiment, the first element E1 may be argon (Ar) gas. In an embodiment, the second material M2 may include nitrogen trifluoride (NF₃). In an embodiment, the second element E2 may be fluorine (F).

In the second chamber 120, the first material M1 (and the first element E1) and the second material M2 (and the second element E2) may react as follows. First, the first radicals E1′ may be formed through the second stage S2. In an embodiment, the first element E1 may be argon (Ar), and the first radicals E1′ may be argon (Ar) radicals. The first radicals E1′ may collide with the second material M2 or the second element E2 disposed in the second chamber 120 to generate radicals of the second element E2, that is, second radicals E2′. In other words, the first radicals E1′ may dissociate the second element E2, and further, the second radicals E2′ from the second material M2. In an embodiment, the second element E2 may be fluorine (F), and the second radicals E2′ may be fluorine (F) radicals.

Although it is shown in FIG. 5 that the first material M1 (and the first element E1) and the second material M2 (and the second element E2) flow into the second chamber, and substantially simultaneously, the second radicals E2′ are produced, the disclosure is not necessarily limited thereto. In an embodiment, after the first material M1 and the second material M2 are injected into the second chamber 120, the first gate 120-1 may be closed, and then the second radicals E2′ may be produced. In an embodiment, unlike FIG. 5, the power portion 122 may operate to additionally supply energy into the second chamber 120.

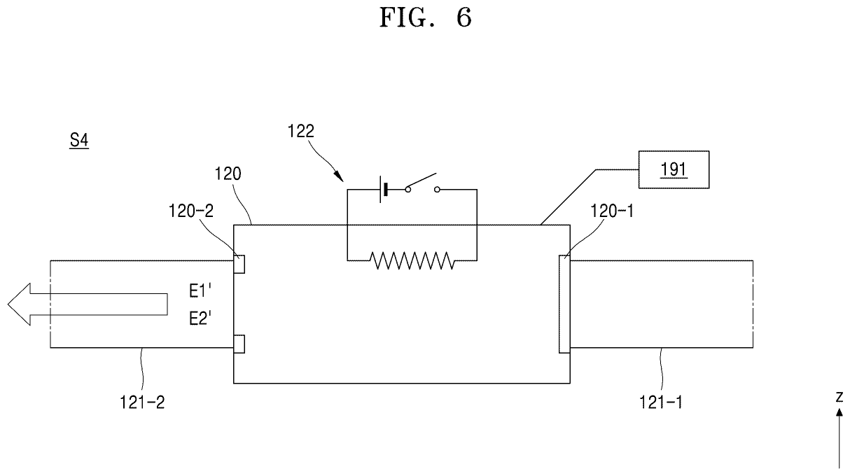

Referring to FIG. 6, a fourth stage S4 may be performed. In the fourth stage S4, the first radicals E1′ and the second radicals E2′ formed through the above-described stages may be discharged from the second chamber 120. In an embodiment, the second gate 120-2 may be opened, and the first radicals E1′ and the second radicals E2′ may flow to the outside of the second chamber 120 toward the first chamber 110 (refer to FIG. 7) through the second injection pipe 121-2, for example. In an embodiment, the first gate 120-1 may be in a closed state.

Referring to FIG. 7, a fifth stage S5 may be performed. In the fifth stage S5, the first radicals E1′ and the second radicals E2′ produced in the second chamber 120 may be guided into the first chamber 110 through the injection pipe 121.

In an embodiment, the first radicals E1′ and the second radicals E2′ may be diffused into the first chamber 110 through the diffuser 170. In an embodiment, the first radicals E1′ and the second radicals E2′ may be guided into the diffuser 170 through a different path from a path of the deposition material. In an embodiment, the first radicals E1′ and the second radicals E2′ may be also diffused into the first chamber 110 through an arbitrary suitable diffusing device (not shown) other than the diffuser 170.

There may be a third material M3 in the first chamber 110. The third material M3 may be the deposition material remaining in the first chamber 110, described with reference to FIG. 2. In the first chamber 110, the following reaction may occur.

First, the second radicals E2′ flowing into the first chamber 110 may react to the third material M3 to produce a fourth material M4. In an embodiment, the third material M3 may be in a solid state, and the fourth material M4 may be in a gaseous state. Because the third material M3 cannot flow, the third material M3 may not be discharged out of the first chamber 110 despite the operation of the pressure adjuster 180. In contrast, because the fourth material M4 may flow, the fourth material M4 may be discharged out of the first chamber 110 when the pressure adjuster 180 operates. The above process of reacting the second radical E2′ with the third material M3 to produce the fourth material M4 and then discharging the fourth material M4 out of the first chamber 110 may be understood as a cleaning process.

In an embodiment, the second radicals E2′ may be fluorine (F) radicals. In an embodiment, the third material M3 may include silicon nitride (SiNₓ) or silicon oxynitride (SiON). In an embodiment, the fourth material M4 may include silicon tetrafluoride (SiF₄). In an embodiment, the fourth material M4, and additionally produced oxygen and/or nitrogen may be discharged out of the first chamber 110 by the operation of the pressure adjuster 180. In an embodiment, the fourth material M4 may flow bypassing the shadow frame 130, the susceptor 140, and/or the mask supporter 150. In an embodiment, while the fourth material M4 is discharged out of the first chamber 110 by the operation of the pressure adjuster 180, a portion of the first radicals E1′ and/or the second radicals E2′ may also be discharged out of the first chamber 110.

A portion of the second radicals E2′ present in the first chamber 110 may recombine with other second radicals E2′. In this case, because the number of second radicals E2′ that may produce the fourth material M4 by reacting with the third material M3 may be reduced, the cleaning process may be delayed. To prevent this, when injecting the second radicals E2′ into the first chamber 110, the first radicals E1′ may be injected together. Similar to what was described above with reference to FIG. 5, the first radicals E1′ may produce the second radicals E2′ even within the first chamber 110. In an embodiment, the first radicals E1′ may dissociate the recombined second radicals E2′ again to produce separated second radicals E2′. Through this, because the second radicals E2′ may be prevented from recombining in the first chamber 110, the delay of the cleaning process may be prevented.

In the above process, the second controller 192 may control the pressure adjuster 180. In an embodiment, the second controller 192 may control the flow rate of a material discharged out of the first chamber 110 by controlling the opening rate of the valve 181 of the pressure adjuster 180. Hereinafter, the opening rate may denote a percentage of a flow rate that may flow through the valve 181 when the valve 181 is partially opened (or partially closed) compared to the maximum flow rate that may flow through the valve 181 when the valve 181 is fully opened. The disclosure is not necessarily limited to this definition and the opening rate may denote various other indicators indicating the degree to which the valve 181 is opened. In an embodiment, the opening rate may denote a percentage of an area through which fluid may pass relative to an area of a cross-section cut perpendicular to the direction of extension of the valve.

In an embodiment, the opening rate of the valve 181 of the pressure adjuster 180 may be about 30% to about 40%. In an embodiment, the opening rate of the valve 181 of the pressure adjuster 180 may be about 30% to about 35%. In an embodiment, the opening rate of the valve 181 of the pressure adjuster 180 may be about 30% to about 32.5%. In an embodiment, the opening rate of the valve 181 of the pressure adjuster 180 may be about 30%.

The first stage S1 (refer to FIG. 3) to the fifth stage S5 may be substantially consecutively performed. Accordingly, in the fifth stage S5, while the inside of the first chamber 110 is cleaned, the first material M1 (and the first element E1) and the second material M2 (and the second element E2) may be supplied to the second chamber 120. Similar to what was described with reference to FIG. 5, the first controller 191 may control the flow rates of the first material M1 and the second material M2 flowing into the second chamber 120. Accordingly, the flow rate of the material flowing from the second chamber 120 into the first chamber 110 may be controlled.

The flow rate of the material injected into the second chamber 120, and further, into the first chamber 110 may be controlled by the first controller 191. The flow rate of the material flowing out from the first chamber 110 to the outside may be controlled by the second controller 192. Accordingly, the amount of material (e.g., gas) present in the first chamber 110 at a predetermined moment may be controlled by the first controller 191 and the second controller 192, or the controller 190, and accordingly, inner pressure 110P of the first chamber 110 may be controlled.

In an embodiment, as the flow rate of the first material M1 or the flow rate of the second material M2 increases, that is, as a sum of the flow rate of the first material M1 and the flow rate of the second material M2 increases, the inner pressure 110P of the first chamber 110 may increase. In an embodiment, as the opening rate of the valve 181 increases, the inner pressure 110P of the first chamber 110 may be reduced. In an embodiment, the inner pressure 110P of the first chamber 110 may be maintained within a preset range by increasing the opening rate of the valve 181 when a sum of the flow rate of the first material M1 and the flow rate of the second material M2 increases and by reducing the opening rate of the valve 181 when a sum of the flow rate of the first material M1 and the flow rate of the second material M2 is reduced. In an embodiment, the inner pressure 110P of the first chamber 110 may be maintained within a preset range by increasing a sum of the flow rate of the first material M1 and the flow rate of the second material M2 when the opening rate of the valve 181 increases, and by reducing a sum of the flow rate of the first material M1 and the flow rate of the second material M2 when the opening rate of the valve 181 is reduced. In an embodiment, the above controlling process may be performed by the first controller 191 and the second controller 192, or the controller 190. In an embodiment, the inner pressure 110P of the first chamber 110 may be maintained at about 1.5 Torr to about 2.5 Torr.

A time duration desired to completely removing the third material M3 in the first chamber 110 may be defined as a cleaning time duration.

One method of shortening the cleaning time duration is to injecting the first radicals E1′ together. Recombination of the second radicals E2′ may be prevented by injecting the first radicals E1′. Accordingly, the cleaning time duration may be shortened by increasing a time duration when the second radicals E2′ are present in a radical state in the first chamber 110.

Another method of shortening the cleaning time duration is to increase a time duration when the second radicals E2′ remain in the first chamber 110 before the second radicals E2′ are discharged to the outside through the pressure adjuster 180. A time duration when the second radicals E2′ remain in a chamber may be represented by Equation 1 below.

$$τ = \frac{PV}{Q} \qquad < Equation 1 >$$

In explaining Equation 1, the chamber may denote the first chamber 110. In Equation 1, T denotes a chamber remaining time duration and has a unit of second (sec). P denotes the inner pressure of the chamber and has a unit of Torr. In an embodiment, P may be the inner pressure 110P of the first chamber 110. V is the volume of the inner space of the chamber and has a unit of L. Q is a flowing velocity and has a unit of Torr*L/sec.

The disclosure is characterized in increasing the chamber remaining time duration T by increasing the chamber inner pressure P. In an embodiment, when the flow rate of the first material M1 flowing into the second chamber 120 is set to about 0, the flow rate of the second material M2 is set to about 32 L/min, and the opening rate of the valve 181 of the pressure adjuster 180 is set to about 100%, P may be about 0.6 Torr. In an embodiment, when the flow rate of the first material M1 flowing into the second chamber 120 is set to about 16 L/min, the flow rate of the second material M2 is set to about 32 L/min, and the opening rate of the valve 181 of the pressure adjuster 180 is set to about 30%, P may be about 2.0 Torr. The value of T may be larger when P is 2.0 Torr than when P is 0.6 Torr, and the cleaning time duration may be shorter accordingly.

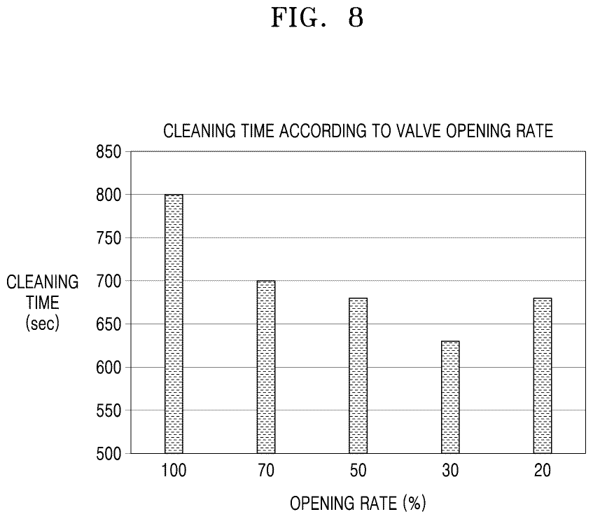

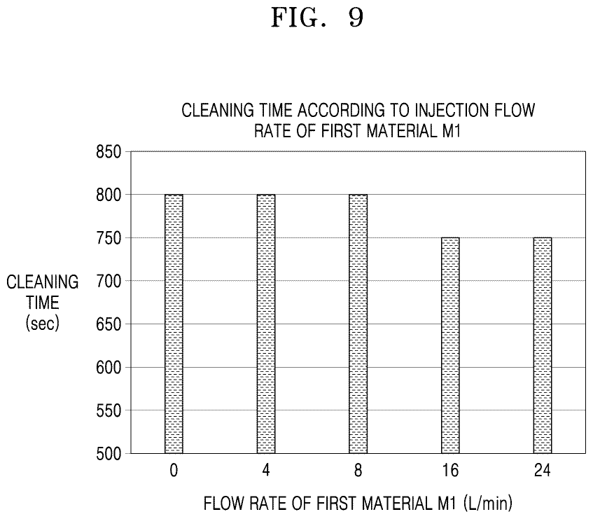

As described above, the flow rate of the material flowing into the second chamber 120 may be controlled by the first controller 120, and the opening rate of the valve 181 may be controlled by the second controller 192. Through this, the chamber remaining time duration T may be controlled, and finally, the cleaning time duration may be controlled. Accordingly, among various combinations of the flow rate of the material flowing into the second chamber 120 and the opening rate of the valve 181, an optimized combination that reduces the cleaning time duration may be found. The optimized combination is described below in detail with reference to FIGS. 8 and 9.

FIG. 8 is a bar graph showing a cleaning time duration according to an opening rate of the valve 181. FIG. 9 is a bar graph showing a cleaning time duration according to an injection flow rate of the first material M1.

Referring to FIG. 8, an x axis of the graph denotes the opening rate of the valve 181 and is expressed as a percentage (%). A y axis of the graph denotes the cleaning time duration and has a unit of sec. The flow rate of the first material M1 (refer to FIG. 7) may be about 16 L/min, and the flow rate of the second material M2 (refer to FIG. 7) may be about 32 L/min.

When the opening rate is about 100%, the cleaning time duration may be about 800 sec. When the opening rate is about 70%, the cleaning time duration may be about 700 sec. When the opening rate is about 50%, the cleaning time duration may be about 680 sec. When the opening rate is about 30%, the cleaning time duration may be about 630 sec. When the opening rate is about 20%, the cleaning time duration may be about 680 sec. As the opening rate decreases, the cleaning time duration gradually decreases and then increases again at about 20%. Accordingly, when the opening rate approaches about 30%, the cleaning time duration is shortest.

Referring to FIG. 9, the x axis of the graph is the flow rate of the first material M1 and has a unit of L/min. The y axis of the graph denotes the cleaning time duration and has a unit of sec. The flow rate of the second material M2 (refer to FIG. 7) is about 32 L/min and the opening rate of the valve 181 may be about 30%.

When the flow rate of the first material M1 is about 0, the cleaning time duration may be about 800 sec. When the flow rate of the first material M1 is about 4 L/min, that is, about 12.5% of the flow rate of the second material M2 (refer to FIG. 7), the cleaning time duration may be about 800 sec. When the flow rate of the first material M1 is about 8 L/min, that is, about 25% of the flow rate of the second material M2 (refer to FIG. 7), the cleaning time duration may be about 800 sec. When the flow rate of the first material M1 is about 16 L/min, that is, about 50% of the flow rate of the second material M2 (refer to FIG. 7), the cleaning time duration may be about 750 sec. When the flow rate of the first material M1 is about 24 L/min, that is, about 75% of the flow rate of the second material M2 (refer to FIG. 7), the cleaning time duration may be about 750 sec. When the flow rate of the first material M1 exceeds 50% of the flow rate of the second material M2 (refer to FIG. 7), the cleaning time duration is shortened, and even when the flow rate of the first material M1 is further increased thereafter, the cleaning time duration is not affected.

Referring to FIGS. 7, 8, and 9, when the flow rate of the first material M1 is 50% or more of the flow rate of the second material M2, and the opening rate of the valve 181 approaches about 30%, the cleaning time duration is shortest.

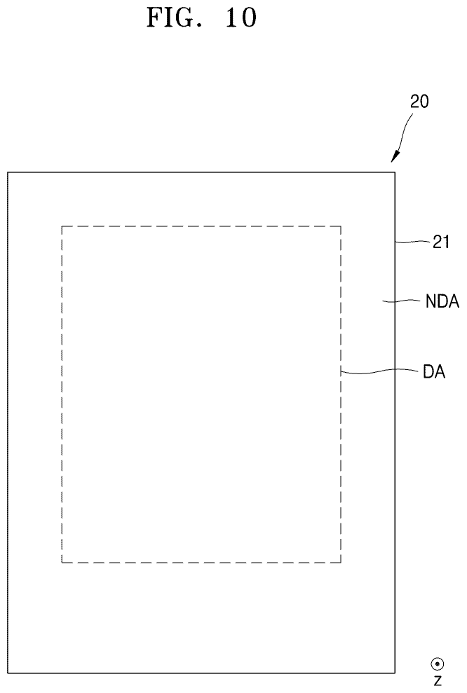

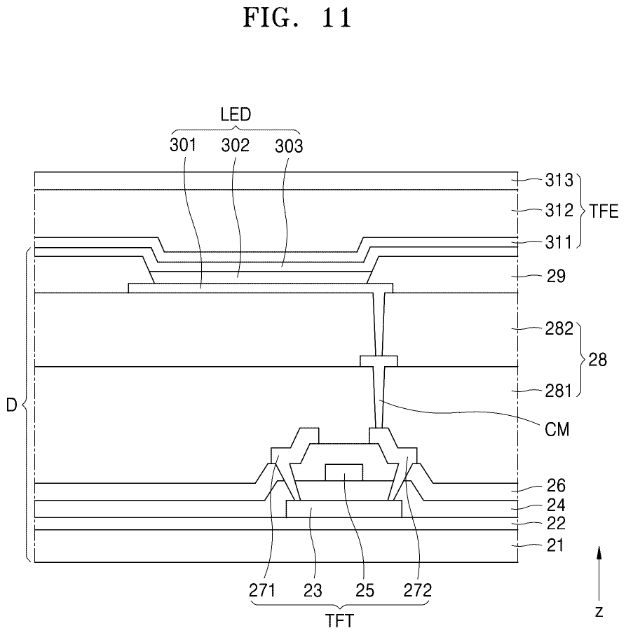

FIG. 10 is a plan view of an embodiment of a display apparatus manufactured using a device for manufacturing a display apparatus or a method of manufacturing a display apparatus. FIG. 11 is a cross-sectional view of an embodiment of a display apparatus 20 manufactured using a device for manufacturing a display apparatus or a method of manufacturing a display apparatus.

Referring to FIGS. 10 and 11, the display apparatus 20 may define a display area DA and a non-display area NDA outside the display area DA on a substrate 21. A light-emitting element LED may be disposed in the display area DA, and a power wiring (not shown) or the like may be disposed in the non-display area NDA. In addition, a pad portion (not shown) may be disposed in the non-display area NDA. A plurality of deposition material patterns may be disposed in the display area DA.

The display apparatus 20 may include the display substrate D and a thin-film encapsulation layer TFE disposed on the display substrate D. The display substrate D may include the substrate 21, a thin-film transistor TFT, a via layer 28, and the light-emitting element LED.

The substrate 21 may include a plastic material or a metal material. In addition, the substrate 21 may include polyimide. The thin-film transistor TFT may be disposed on the substrate 21, the via layer 28 is disposed to cover the thin-film transistor TFT, and the light-emitting element LED may be disposed on the via layer 28.

A buffer layer 22 including an organic compound and/or an inorganic compound may be further disposed on the upper surface of the substrate 21. The buffer layer 22 may include or consist of SiOₓ (x≥1) and/or SiNₓ (x≥1).

An active layer 23 disposed in a preset pattern may be disposed on the buffer layer 22, and then, the active layer 23 may be buried by a gate insulating layer 24. The active layer 23 may include a source region and a drain region and further include a channel region therebetween. The active layer 23 may be formed to include or consist of various materials. In an embodiment, the active layer 23 may include or consist of an inorganic semiconductor material such as amorphous silicon or crystalline silicon. In another embodiment, the active layer 23 may include or consist of an oxide semiconductor. In another embodiment, the active layer 23 may include or consist of an organic semiconductor material. Hereinafter, for convenience of description, the case where the active layer 23 includes amorphous silicon is mainly described in detail.

The active layer 23 may be formed by forming an amorphous silicon layer on the buffer layer 23, then crystalizing the amorphous silicon to form a polycrystalline silicon layer, and patterning the polycrystalline silicon layer. The source region and the drain region of the active layer 23 may be doped with impurities depending on the kind of the thin-film transistor such as a driving thin-film transistor, a switching thin-film transistor, or the like.

A gate electrode 25 corresponding to the active layer 23, and an inter-insulating layer 26 burying the gate electrode 25 may be disposed on the upper surface of the gate insulating layer 24. Contact holes are defined in the inter-insulating layer 26 and the gate insulating layer 24, and then, a source electrode 271 and a drain electrode 272 may be disposed on the inter-insulating layer 26 to be respectively in contact with the source region and the drain region of the active layer 23.

The via layer 28 may be disposed on the thin-film transistor TFT, and a pixel electrode 301 of the light-emitting element LED may be disposed on the via layer 28. The via layer 28 may include a first via layer 281 and a second via layer 282 on the first via layer 281, and the first via layer 281 buries the source electrode 271 and the drain electrode 273. The via layer 28, e.g., the first and second via layers 281 and 282 may include an inorganic material and/or an organic material, may be formed as planarization layers such that the upper surfaces thereof are flat regardless of the curvature of the lower layer, or formed to be curved along the curvature of the lower layer.

A via hole may be defined in the first via layer 281, and at least a portion of a contact metal CM may be disposed in the via hole of the first via layer 281. A via hole may be defined also in the second via layer 282, and a portion of the pixel electrode 301 may be disposed in the via hole of the second via layer 282. The pixel electrode 301 contacts the drain electrode 272 of the thin-film transistor TFT through the via hole defined in the via layer 28. In an embodiment, the contact metal CM may contact the drain electrode 272 through the via hole defined in the first via layer 281, and the pixel electrode 301 contacts the contact metal CM through the via hole defined in the second via layer 282, and thus, is connected to the drain electrode 272.

The pixel electrode 301 is disposed on the via layer 28, and then, a pixel-defining layer 29 may include an organic material and/or an inorganic material to cover the pixel electrode 301 and the via layer 28. The pixel-defining layer 29 may be open to expose a portion of the pixel electrode 301.

An intermediate layer 302 and an opposite electrode 303 are disposed on the pixel electrode 301. In an embodiment, the opposite electrode 303 may be disposed on the intermediate layer 302 and the pixel-defining layer 29. The pixel electrode 301 may serve as an anode electrode, and the opposite electrode 303 may serve as a cathode electrode. The polarities of the pixel electrode 301 and the opposite electrode 303 may be reversed. The pixel electrode 301 and the opposite electrode 303 may be insulated from each other by the intermediate layer 302, and light is emitted from an organic emission layer by applying voltages of different polarities to the intermediate layer 302.

The intermediate layer 302 may include an organic emission layer. In another embodiment, the intermediate layer 302 may include the organic emission layer, and, in addition to the organic emission layer, further include at least one of a hole injection layer, a hole transport layer, an electron transport layer, and an electron injection layer. The embodiment is not necessarily limited thereto and the intermediate layer 302 may include the organic emission layer and further include various other layers (not shown).

One unit pixel includes a plurality of sub-pixels and the plurality of sub-pixels may emit light of various colors. In an embodiment, the plurality of sub-pixels may include sub-pixels which respectively emit red, green, and blue light, or include sub-pixels (not shown) which respectively emit red, green, blue, and white light. The sub-pixel may include one intermediate layer 302.

The thin-film encapsulation layer TFE may be disposed to cover the light-emitting element LED. The thin-film encapsulation layer TFE may include a plurality of inorganic layers or include an inorganic layer and an organic layer. The inorganic layer of the thin-film encapsulation layer TFE may be a single layer or a stack layer including a metal oxide or metal nitride. In an embodiment, the inorganic layer may include one of SiNₓ, Al₂O₃, SiO₂, and TiO₂. The organic layer of the thin-film encapsulation layer TFE may include polymer and be a single layer or a stack layer including one of polyethylene terephthalate, polyimide, polycarbonate, epoxy, polyethylene, and polyacrylate, for example. In an embodiment, an uppermost layer 313 of the thin-film encapsulation layer TFE exposed to the outside may include an inorganic layer to prevent moisture transmission to the light-emitting element. The thin-film encapsulation layer TFE may be formed by the device for manufacturing the display apparatus or the method of manufacturing the display apparatus described above. In an embodiment, each of a lowermost layer 311 and an intermediate layer 312 of the thin-film encapsulation layer TFE may the organic layer or the inorganic layer, for example.

In an embodiment, the flow rate of each of the first material and the second material flowing into the second chamber may be controlled, the flow rate of gas flowing out of the first chamber to the outside may be controlled, the pressure in the first chamber may be controlled, and thus, a time duration when cleaning materials (e.g., the radicals of the first element and the radicals of the second element) remain in the first chamber may be increased. Accordingly, a time duration desired to clean the inside of the first chamber may be reduced.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A device for manufacturing a display apparatus, the device comprising:
a first chamber;
a second chamber connected to the first chamber;
a first controller which controls the second chamber;
a pressure adjuster connected to the first chamber; and
a second controller which controls the pressure adjuster,
wherein the first controller, while a cleaning process of the first chamber is performed, controls at least one of a flow rate of a first material flowing into the second chamber and a flow rate of a second material flowing into the second chamber, and the second controller, while the cleaning process of the first chamber is performed, controls an opening rate of the pressure adjuster and maintains a pressure in the first chamber at a preset range.

2. The device of claim 1, wherein the first material includes a first element, and the device for manufacturing the display apparatus generates first radicals of the first element by applying energy to the first material in the second chamber.

3. The device of claim 2, wherein the first element is argon.

4. The device of claim 2, wherein the second material includes a second element, and the device for manufacturing the display apparatus generates second radicals of the second element by the first radicals of the first element in the second chamber.

5. The device of claim 4, wherein the second element is fluorine.

6. The device of claim 4, wherein the first radicals of the first element and the second radicals of the second element, generated in the second chamber, are injected into the first chamber.

7. The device of claim 1, wherein the opening rate of the pressure adjuster is about 30% to about 35%.

8. The device of claim 1, wherein the flow rate of the second material flowing into the second chamber is 50% or more of the flow rate of the first material flowing into the second chamber.

9. The device of claim 1, wherein the preset range of the pressure in the first chamber is about 1.5 Torr to about 2.5 Torr.

10. A method of manufacturing a display apparatus, the method comprising:
depositing a deposition material on a substrate in a first chamber; and
cleaning the deposition material remaining in the first chamber,
wherein, in the cleaning the deposition material, at least one of a flow rate of a first material flowing into a second chamber connected to the first chamber, and a flow rate of a second material flowing into the second chamber is adjusted, and an opening rate of a pressure adjuster connected to the first chamber is adjusted, thereby maintaining pressure in the first chamber at a preset range.

11. The method of claim 10, wherein the first material includes a first element, and the method further comprises generating first radicals of the first element by applying energy to the first material in the second chamber.

12. The method of claim 11, wherein the first element is argon.

13. The method of claim 11, wherein the second material includes a second element, and the method further comprises generating second radicals of the second element by the first radicals of the first element in the second chamber.

14. The method of claim 13, wherein the second element is fluorine.

15. The method of claim 13, wherein, in the generating the second radicals of the second element, the first material and the second material are injected together at a preset ratio into the second chamber.

16. The method of claim 13, further comprising injecting, into the first chamber, the first radicals of the first element and the second radicals of the second element, generated in the second chamber.

17. The method of claim 10, wherein the opening rate of the pressure adjuster is about 30% to about 35%.

18. The method of claim 10, wherein the flow rate of the first material flowing into the second chamber is 50% or more of the flow rate of the second material flowing into the second chamber.

19. The method of claim 10, wherein the preset range of the pressure in the first chamber is about 1.5 Torr to about 2.5 Torr.

20. The method of claim 10, wherein, in the maintaining the pressure in the first chamber at the preset range, the opening rate of the pressure adjuster is increased when a sum of the flow rate of the first material and the flow rate of the second material is increased, and the opening rate of the pressure adjuster is reduced when a sum of the flow rate of the first material and the flow rate of the second material is reduced.
